(19) United States
(12) Patent Application Publication
(10) Pub. No.: US 2021/0318619 A1
(43) Pub. Date: Oct. 14, 2021

(54) COMPOSITION, METHOD OF PRODUCING SUBSTRATE, METHOD OF FORMING PATTERN, AND METHOD OF FORMING REVERSE PATTERN

(71) Applicant: JSR CORPORATION, Tokyo (JP)

(72) Inventors: Yuusuke OOTSUBO, Tokyo (JP); Tatsuya SAKAI, Tokyo (JP); Kazunori SAKAI, Tokyo (JP)

(73) Assignee: JSR CORPORATION, Tokyo (JP)

(21) Appl. No.: 17/356,582

(22) Filed: Jun. 24, 2021

Related U.S. Application Data
(63) Continuation of application No. PCT/JP2019/050710, filed on Dec. 24, 2019.

(30) Foreign Application Priority Data
Dec. 26, 2018 (JP) 2018-242573
Mar. 29, 2019 (JP) 2019-067945
Oct. 18, 2019 (JP) 2019-191492

(51) Int. Cl. G03F 7/11; C09D 7/20; C09D 1/00; G03F 7/16

(52) U.S. Cl. CPC G03F 7/11; G03F 7/16; C09D 1/00; C09D 7/20

(57) ABSTRACT

A composition includes: a cobalt-containing compound not containing a cobalt-carbon bond; and a solvent. The composition is capable of forming a coating film. The solvent preferably includes an organic solvent, and the organic solvent preferably includes an alcohol solvent. A method of producing a substrate includes applying the composition directly or indirectly on a substrate to form a coating film.

### CROSS-REFERENCE TO RELATED APPLICATIONS

The present application is a continuation application of International Application No. PCT/JP2019/050710, filed Dec. 24, 2019, which claims priority to Japanese Patent Application No. 2018-242573 filed Dec. 26, 2018, to Japanese Patent Application No. 2019-067945 filed Mar. 29, 2019, and to Japanese Patent Application No. 2019-191492 filed Oct. 18, 2019. The contents of these applications are incorporated herein by reference in their entirety.

### BACKGROUND OF THE INVENTION

### Field of the Invention

The present invention relates to a composition, a method of producing a substrate, a method of forming a pattern, and a method of forming a reverse pattern.

### Description of the Related Art

In manufacturing semiconductor devices, a method has been employed in which a cobalt-containing film is formed on a substrate by chemical vapor deposition (CVD) or atomic layer deposition (ALD) using an organic metal precursor (see PCT International Publication No. 2011/017068).

### SUMMARY OF THE INVENTION

According to an aspect of the present invention, a composition includes: a cobalt-containing compound not containing a cobalt-carbon bond; and a solvent. The composition is capable of forming a coating film.

According to another aspect of the present invention, a method of producing a substrate includes applying a composition directly or indirectly on a substrate to form a coating film. The composition includes: a cobalt-containing compound not containing a cobalt-carbon bond; and a solvent.

According to a further aspect of the present invention, a method of forming a pattern includes applying the above-mentioned composition directly or indirectly on a substrate to form a resist underlayer film. A composition for forming an organic resist film is applied directly or indirectly on the resist underlayer film to form an organic resist film. The organic resist film is exposed to a radioactive ray. The organic resist film exposed is developed to form an organic resist pattern. The resist underlayer film is brought into contact with a chlorine gas using the organic resist pattern as a mask. The resist underlayer film is removed with a removing liquid containing water or an organic solvent.

According to a further aspect of the present invention, a method of forming a reverse pattern includes forming an organic underlayer film directly or indirectly on a substrate. A resist pattern is formed directly or indirectly on the organic underlayer film. A film for forming a reverse pattern is formed on the resist pattern by applying the above-mentioned composition. A reverse pattern is formed by removing the resist pattern.

### DESCRIPTION OF EMBODIMENTS

The organic metal precursor used in the conventional method of forming a cobalt-containing film has insufficient storage stability. Furthermore, a long period of time is required to form a cobalt-containing film having a thickness of several tens of nanometers; thus, productivity is poor.

According to one embodiment of the invention, a composition contains:

a cobalt-containing compound not having a cobalt-carbon bond (hereinafter, may be also referred to as “(A) compound” or “compound (A)”); and

a solvent (hereinafter, may be also referred to as “(B) solvent” or “solvent (B)”).

Another embodiment of the invention is a method of producing a substrate, the method including applying a composition directly or indirectly on a substrate, wherein

the composition contains:
a cobalt-containing compound not having a cobalt-carbon bond; and
a solvent.

The composition of the one embodiment of the present invention is superior in storage stability. Due to using the composition for forming a coating film of the one embodiment of the present invention, the method of the another embodiment of the present invention enables forming a cobalt-containing film which is superior in conductivity and an embedding property. Therefore, these can be suitably used in forming a cobalt-containing film in a semiconductor field, a battery material field, an antistatic field, a touch panel sensor field, and the like. Hereinafter, embodiments of the present invention will be explained in detail.

### Composition for Forming Coating Film

According to one embodiment of the present invention, a composition for forming a coating film contains the compound (A) and the solvent (B). The composition for forming a coating film may also contain optional component(s), within a range not leading to impairment of the effects of the present invention.

The composition for forming a coating film can be used in a method of forming a pattern, described later. Thus, the composition for forming a coating film can be suitably used as a composition for forming a pattern.

The composition for forming a coating film is used in a method of forming a reverse pattern, described later. Thus, the composition for forming a coating film can be suitably used as a composition for forming a reverse pattern.

Hereinafter, each component contained in the composition for forming a coating film will be described.

(A) Compound

The compound (A) is a cobalt-containing compound not having a cobalt-carbon bond. The composition for forming a coating film may contain two or more types of the compound (A). The “cobalt-containing compound” as referred to herein means a compound containing a cobalt atom. The “cobalt-carbon bond” as referred to herein means a covalent bond or a coordinate bond between a cobalt atom and a carbon atom included in, for example, a cobalt-carbonyl complex, a cobalt-cyano complex, a cobaltocene complex, a cobalt-alkyl complex, a cobalt-acyl complex, or the like. The composition for forming a coating film is superior in storage stability due to using, as the compound (A), a compound not having the cobalt-carbon bond.

The compound (A) may contain one, or a plurality of cobalt atoms. Furthermore, a valency of the cobalt atom in the compound (A) may be 0, 1, 2, 3, or the like. Of these, in light of further improving storage stability, the valency is preferably 2 or 3.

The compound (A) is exemplified by a cobalt salt, a complex including cobalt and a ligand, and a combination thereof.

Exemplary cobalt salts include: oxoacid salts such as nitrates, sulfates, phosphates, carboxylates, perchlorates, carbonates, and borates; thiocyanates; sulfamates; halides such as fluorides, chlorides, bromides, and iodides; hydroxides; and the like. Examples of the carboxylates include acetates, stearates, naphthenates, citrates, oxalates, succinates, and the like. Of these, in light of further improving storage stability, the oxoacid salts are preferred, and nitrates, sulfates, and carboxylates are further preferred.

The ligand constituting the complex is exemplified by a monodentate ligand, a polydentate ligand, and the like.

Exemplary monodentate ligands include a hydroxy ligand, an amido ligand, a halogen ligand, an alkoxy ligand, an acyloxy ligand, a phosphine ligand, an amine ligand, an ammonia ligand, and the like.

Examples of the amido ligand include an unsubstituted amido ligand (NH₂), a methylamido ligand (NHCH₃), a dimethylamido ligand (N(CH₃)₂), a diethylamido ligand (N(C₂H₅)₂), a dipropylamido ligand (N(C₃H₇)₂), and the like.

Examples of the halogen ligand include a fluorine ligand, a chlorine ligand, a bromine ligand, an iodine ligand, and the like.

Examples of the alkoxy ligand include a methoxy ligand, an ethoxy ligand, a propoxy ligand, a butoxy ligand, and the like.

Examples of the acyloxy ligand include an acetoxy ligand, an ethylyloxy ligand, a butyryloxy ligand, a t-butyryloxy ligand, a t-amylyloxy ligand, an n-hexanecarbonyloxy ligand, an n-octanecarbonyloxy ligand, and the like.

Examples of the amine ligand include a methylamine ligand, a dimethylamine ligand, a piperidine ligand, a morpholine ligand, a pyridine ligand, and the like.

Examples of the phosphine ligand include a trimethylphosphine ligand, a triethylphosphine ligand, a tributylphosphine ligand, a triphenylphosphine ligand, and the like.

Exemplary polydentate ligands include an oxygen bidentate ligand, a nitrogen bidentate ligand, a nitrogen tridentate ligand, a nitrogen tetradentate ligand, a nitrogen bidentate oxygen bidentate ligand, a nitrogen bidentate oxygen tetradentate ligand, a phosphorus bidentate ligand, and the like.

Examples of the oxygen bidentate ligand include a ligand derived from a dicarboxylic acid, a ligand derived from a hydroxy acid ester, a ligand derived from a β-diketone, a ligand derived from a β-ketoester, a ligand derived from a β-carboxylic acid ester, a ligand derived from a catechol or a substituted product thereof, and the like.

Examples of the dicarboxylic acid include oxalic acid, malonic acid, succinic acid, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-ketoester include acetoacetic acid esters, α-alkyl-substituted acetoacetic acid esters, β-ketopentanoic acid esters, benzoylacetic acid esters, 1,3-acetone dicarboxylic acid esters, and the like.

Examples of the β-carboxylic acid ester include malonic acid diesters, α-alkyl-substituted malonic acid diesters, α-cycloalkyl-substituted malonic acid diesters, α-aryl-substituted malonic acid diesters, and the like.

Examples of the nitrogen bidentate ligand include: a ligand derived from 2,2′-bipyridyl or a substituted product thereof; a ligand derived from 1,8-naphthylidine or a substituted product thereof; a ligand derived from 2-(1H-pyrazol-1-yl)pyridine or a substituted product thereof; a ligand derived from 1,10-phenanthroline or a substituted product thereof; a ligand derived from ethylenediamine, propanediamine, butanediamine, or a substituted product of these; and the like.

Examples of the nitrogen tridentate ligand include a ligand derived from 2,6-di(1H-pyrazol-1-yl)pyridine or a substituted product thereof, a ligand derived from α,α′,α″-tripyridyl or a substituted product thereof, a ligand derived from diethylenetriamine or a substituted product thereof, a ligand derived from 1,4,7-triazacyclononane or a substituted product thereof, and the like.

Examples of the nitrogen tetradentate ligand include a ligand derived from phthalocyanine or a substituted product thereof, a ligand derived from naphthocyanine or a substituted product thereof, a ligand derived from porphyrin or a substituted product thereof, a ligand derived from porphycene or a substituted product thereof, a ligand derived from triethylenetetramine or a substituted product thereof, a ligand derived from 1,4,7,10-tetraazacyclododecane or a substituted product thereof, a ligand derived from 1,4,8,11-tetraazacyclotetradecane or a substituted product thereof, a ligand derived from tris(2-aminoethyl)amine or a substituted product thereof, and the like.

Examples of the nitrogen bidentate oxygen bidentate ligand include a ligand derived from N,N′-bis(salicylidene)ethylenediamine or a substituted product thereof, a ligand derived from N,N′-bis(3-hydroxy-2-butenylidene)ethylenediamine or a substituted product thereof, and the like.

Examples of the nitrogen bidentate oxygen tetradentate ligand include a ligand derived from ethylenediamine tetraacetic acid, and the like.

Examples of the phosphorus bidentate ligand include: phosphine ligands such as 1,1-bis(biphenylphosphino)methane, 1,2-bis(biphenylphosphino)ethane, 1,3-bis(biphenylphosphino)propane, 2,2′-bis(biphenylphosphino)-1,1′-binaphthyl, and 1,1′-bis(biphenylphosphino)ferrocene; and the like.

The lower limit of a proportion of the compound (A) with respect to total components other than the solvent (B) in the composition for forming a coating film is preferably 30% by mass, more preferably 50% by mass, and still more preferably 60% by mass. The proportion may be 100% by mass.

The lower limit of a proportion of the compound (A) in the composition for forming a coating film is preferably 1% by mass, more preferably 5% by mass, still more preferably 10% by mass, and particularly preferably 15% by mass. The upper limit of the proportion is preferably 70% by mass, more preferably 50% by mass, still more preferably 30% by mass, and particularly preferably 25% by mass.

(B) Solvent

The solvent (B) may be used without particular limitation as long as it is capable of dissolving or dispersing the compound (A), and optional component(s) which may be contained as needed. The solvent (B) may be used either alone of one type, or in a combination of two or more types thereof.

The solvent (B) is exemplified by an organic solvent (hereinafter, may be also referred to as “(b) organic solvent” or “organic solvent (b)”), water, and the like. The “organic solvent” as referred to herein is an organic solvent which is in a liquid state at 25° C. When the solvent (B) contains the organic solvent (b), the lower limit of a proportion of the organic solvent (b) in the solvent (B) is preferably 20% by mass, more preferably 50% by mass, still more preferably 70% by mass, and particularly preferably 90% by mass. The proportion of the organic solvent (b) in the solvent (B) may be 100% by mass.

Exemplary organic solvents (b) include an alcohol solvent, a ketone solvent, an ether solvent, an ester solvent, a nitrogen-containing solvent, and the like. The organic solvent (b) may be used either alone of one type, or in a combination of two or more types thereof.

Examples of the alcohol solvent include: monohydric alcohols such as methyl alcohol, ethyl alcohol, n-propyl alcohol, and n-butyl alcohol; polyhydric alcohols such as ethylene glycol, 1,2-propanediol, 1,2-butanediol, triethanolamine, diethylene glycol, and glycerin; polyhydric alcohol partial ethers such as propylene glycol monomethyl ether and propylene glycol monoethyl ether; lactic acid esters such as ethyl lactate and butyl lactate; hydrazino alcohols such as 2-hydrazino ethanol and 3-hydrazino propanol; hydroxyketone hydrazones such as 1-hydroxy-2-propanehydrazone and 1-hydroxy-2-butanonehydrazone; and the like.

Examples of the ketone solvent include: chain ketones such as methyl ethyl ketone and methyl isobutyl ketone; cyclic ketones such as cyclohexanone; and the like.

Examples of the ether solvent include chain ethers such as n-butyl ether; cyclic ethers such as tetrahydrofuran and 1,4-dioxane; and the like.

Examples of the ester solvent include carbonates such as diethyl carbonate; acetic acid esters such as methyl acetate and ethyl acetate; lactones such as γ-butyrolactone; polyhydric alcohol partial ether carboxylates such as diethylene glycol monomethyl ether acetate and propylene glycol monomethyl ether acetate; and the like.

Examples of the nitrogen-containing solvent include chain nitrogen-containing compounds such as N,N-dimethylacetamide; cyclic nitrogen-containing compounds such as N-methylpyrrolidone; and the like.

The organic solvent (b) preferably contains the alcohol solvent. The alcohol solvent is preferably the monohydric alcohol, the polyhydric alcohol partial ether, the lactic acid ester, the hydrazide alcohol, or the hydroxyketone hydrazone. When the organic solvent (b) contains the alcohol solvent, conductivity and the embedding property of the cobalt-containing film formed from the composition for forming a coating film can be further improved. It is thought that when the organic solvent (b) contains the alcohol solvent, cobalt atoms in the coating film are reduced by the alcohol solvent in a step of heating the coating film to have a valency of 0, whereby conductivity of the cobalt-containing film is improved. In the case of the organic solvent (b) containing the alcohol solvent, the lower limit of a proportion of the alcohol solvent in the organic solvent (b) is preferably 1% by mass, more preferably 10% by mass, still more preferably 50% by mass, and particularly preferably 80% by mass. The proportion of the alcohol solvent in the organic solvent (b) may be 100% by mass.

When the solvent (B) contains water, the upper limit of a proportion of water in the solvent (B) is preferably 50% by mass, more preferably 40% by mass, and further preferably 30% by mass. The lower limit of the proportion of water is, for example, 0.01% by mass.

The lower limit of a proportion of the solvent (B) in the composition for forming a coating film is preferably 30% by mass, more preferably 50% by mass, still more preferably 60% by mass, particularly preferably 70% by mass, and further particularly preferably 75% by mass. The upper limit of the proportion is preferably 99% by mass, more preferably 95% by mass, still more preferably 90% by mass, and particularly preferably 85% by mass.

The lower limit of a content of the solvent (B) with respect to 100 parts by mass of the compound (A) is preferably 50 parts by mass, more preferably 100 parts by mass, still more preferably 200 parts by mass, and particularly preferably 300 parts by mass. The upper limit of the content is preferably 10,000 parts by mass, more preferably 2,000 parts by mass, still more preferably 1,000 parts by mass, and particularly preferably 500 parts by mass.

When the proportion or the content of the solvent (B) is made to fall within the above ranges, storage stability of the composition for forming a coating film can be further improved.

Optional Component(s)

The composition for forming a coating film may contain, as optional component(s), an other organic compound aside from the solvent (B) (hereinafter, may be also referred to as “(C) other organic compound” or “other organic compound (C)”), a metal-containing compound aside from the compound (A) (hereinafter, may be also referred to as “other metal-containing compound”), and the like. The optional component(s) may be used either alone of one type, or in a combination of two or more types thereof.

(C) Other Organic Compound

The other organic compound (C) is exemplified by a compound having an alcoholic hydroxyl group, a compound having a phenolic hydroxyl group, a nitrogen-containing compound, oxalic acid, and the like. When the exemplified compound(s) is/are used as the other organic compound (C), conductivity and the embedding property of the cobalt-containing film formed from the composition for forming a coating film can be further improved.

Exemplary compounds having an alcoholic hydroxyl group include a hydroxy acid or a salt thereof, a saccharide compound, a compound having a plurality of alcoholic hydroxyl groups, and the like.

Examples of the compound having a plurality of alcoholic hydroxyl groups include ascorbic acid or a salt thereof, erythorbic acid or a salt thereof, trimethylolpropane, diethanolamine, pentaerythritol, dipentaerythritol, adamantanediol, adamantanetriol, adamantanetetraol, 1,3-dimethyladamantane-5,7-diol, polyethylene glycol, polyvinyl alcohol, and the like.

Examples of the hydroxy acid include glycolic acid, lactic acid, 3-hydroxypropionic acid, glyeric acid, tartronic acid, malic acid, tartaric acid, citric acid, 10-hydroxydecanoic acid, tropic acid, benzylic acid, and the like.

Examples of the saccharide compound include erythritol, mesoerythritol, ribitol, xylitol, sorbitol, maltitol, glucose, fructose, lactose, arabinose, galactose, sucrose, maltose, trehalose, gluconic acid, glyceraldehyde, and the like.

Examples of the compound having a phenolic hydroxyl group include gallic acid or a salt or ester thereof, salicylic acid or a salt or ester thereof, tocopherol or a derivative thereof, 2,6-di-t-butyl-4-methylphenol, t-butyl-methoxyphenol, catechol, resorcinol, hydroquinone, pyrogallol, phloroglucinol, 1,2,4-trihydroxybenzene, dihydroxynaphthalene, rosmarinic acid, tannic acid, caffeic acid, dihydrocaffeic acid, quercetin, and the like.

Examples of the nitrogen-containing compound include hydrazine derivatives, e.g.: hydrazides such as formic acid hydrazide, acetic acid hydrazide, cyanoacetic acid hydrazide, trifluoroacetic acid hydrazide, propionic acid hydrazide, cyclohexanecarboxylic acid hydrazide, benzoic acid hydrazide, p-toluic acid hydrazide, salicylic acid hydrazide, 3-hydroxy-2-naphthoic acid hydrazide, p-hydroxybenzoic acid hydrazide, 2-ethoxybenzoic acid hydrazide, succinic acid dihydrazide, maleic acid dihydrazide, adipic acid dihydrazide, sebacic acid dihydrazide, dodecanedioic acid dihydrazide, and isophthalic acid dihydrazide; hydrazones such as benzophenone hydrazone, 9-fluorenone hydrazone, anthraquinone monohydrazone, and salicylaldehyde hydrazone; carbazates such as methylcarbazate, ethylcarbazate, t-butylcarbazate, and benzylcarbazate; and the like.

Other Metal-Containing Compound

Examples of the other metal-containing compound include: compounds containing a metal other than cobalt such as nickel, iron, ruthenium, copper, silver, gold, palladium, platinum, zinc, aluminum, tin, tungsten, zirconium, titanium, tantalum, or molybdenum; and the like. The other metal-containing compound may be a metal salt, or may be a complex having a metal and a ligand.

In the case in which the composition for forming a coating film contains the other metal-containing compound, the lower limit of a proportion of the compound (A) with respect to total metal-containing compounds contained in the composition for forming a coating film is preferably 50% by mass, more preferably 70% by mass, still more preferably 90% by mass, and particularly preferably 99% by mass. The proportion of the compound (A) with respect to total metal-containing compounds contained in the composition for forming a coating film in total may be 100% by mass.

Preparation Procedure of Composition for Forming Coating Film

The composition for forming a coating film may be prepared, for example, by mixing the compound (A), the solvent (B), and as needed, the optional component(s) in a certain ratio, preferably followed by filtering a thus resulting mixture through a filter, etc. having a pore size of no greater than 0.2 μm.

Method of Producing Substrate

The method of producing a substrate of the another embodiment of the present invention includes a step of applying a composition directly or indirectly on a substrate (hereinafter, may be also referred to as “applying step”) to form a coating film. In the method of producing a substrate, the composition described above as the composition for forming a coating film of the one embodiment of the present invention (hereinafter, may be also referred to as “composition (I)”) is used as the composition.

Due to using the composition for forming a coating film, described above, the method of producing a substrate enables forming a cobalt-containing film which is superior in conductivity and the embedding property.

After the applying step, the method of producing a substrate may further include a step of heating the coating film (hereinafter, may be also referred to as “heating step”).

Hereinafter, each step included in the method of producing a substrate will be described.

Applying Step

In this step, the composition (I) is applied directly or indirectly on the substrate. In this step, the coating film is formed directly or indirectly on the substrate. An applying procedure is not particularly limited, and for example, an appropriate procedure such as spin coating, cast coating, or roll coating may be employed. The case of applying the composition (I) indirectly on the substrate may be exemplified by a case in which a substrate surface modification film has been formed on the substrate. The substrate surface modification film is a film in which an angle of contact with water differs from that of the coating film.

The substrate is exemplified by a metal substrate, a silicon wafer, and the like. The “metal substrate” as referred to herein means a substrate containing a metal atom in at least a part of a surface layer thereof. The metal atom contained in the metal substrate is not particularly limited as long as it is an atom of a metal element. Silicon and boron do not fall under the category of metal elements. Examples of the metal atom include an atom of copper, iron, zinc, cobalt, aluminum, tin, tungsten, zirconium, titanium, tantalum, germanium, molybdenum, ruthenium, gold, silver, platinum, palladium, nickel, or the like. Examples of the metal substrate include a substrate made of the metal, a silicon wafer covered with the metal, and the like. A silicon nitride film, an alumina film, a silicon dioxide film, a tantalum nitride film, a titanium nitride film, or the like may be formed on a part of the metal substrate.

The substrate may be a pattern-unformed substrate, or may be a pattern-formed substrate.

The pattern of the pattern-formed substrate is exemplified by: a line-and-space pattern or a trench pattern, with line widths of space portions being no greater than 2,000 nm, no greater than 1,000 nm, no greater than 500 nm, or no greater than 50 nm; a hole pattern, with diameters of holes being no greater than 300 nm, no greater than 150 nm, no greater than 100 nm, or no greater than 50 nm; and the like.

With respect to dimensions of the pattern formed on the substrate, an exemplary fine pattern may have: a height of no less than 100 nm, no less than 200 nm, or no less than 300 nm; a width of no greater than 50 nm, no greater than 40 nm, or no greater than 30 nm; and an aspect ratio (pattern height/pattern width) of no less than 3, no less than 5, or no less than 10.

In the case in which the pattern-formed substrate is used as the substrate, a coating film formed by applying the composition for forming a coating on the substrate can preferably be embedded into recessed portions of the pattern. For example, in the case of using the substrate in which a silicon dioxide pattern is formed on a part of the metal substrate, the coating film capable of being embedded into recessed portions of the pattern enables a conducting circuit to be formed.

Heating Step

This step is an optional step of heating the coating film. It is considered that in this step, conductivity of the coating film is improved. By heating the coating film, it is considered that cobalt atoms in the coating film are reduced, to have a valency of zero, whereby conductivity of the cobalt-containing film is improved.

Examples of the atmosphere in which the coating film is heated include a nitrogen atmosphere, a hydrogen atmosphere, open air, and the like. When the coating film is heated in a hydrogen atmosphere, it is considered that reduction of cobalt atoms in the coating film is further promoted, whereby conductivity of the cobalt-containing film is further improved. The lower limit of a temperature in the heating is preferably 200° C., more preferably 300° C., and still more preferably 400° C. The upper limit of the temperature is preferably 700° C., more preferably 600° C., and still more preferably 550° C. The lower limit of a time period of the heating is preferably 10 sec, more preferably 60 sec, and still more preferably 180 sec. The upper limit of the time period is preferably 3,000 sec, more preferably 1,200 sec, and still more preferably 600 sec.

Before heating the coating film, preheating may be conducted at a temperature of no less than 60° C. and no greater than 150° C. The lower limit of a time period of the preheating is preferably 10 sec, and more preferably 30 sec. The upper limit of the time period is preferably 300 sec, and more preferably 180 sec.

In the method of producing a substrate, exposing and heating may be employed in combination. A radioactive ray to be used in the exposing may be appropriately selected from: electromagnetic waves such as a visible light ray, an ultraviolet ray, a far ultraviolet ray, an X-ray, and a γ-ray; and particle rays such as an electron beam, a molecular beam, and an ion beam.

The lower limit of an average thickness of the cobalt-containing film to be formed is preferably 1 nm, more preferably 10 nm, and still more preferably 30 nm. The upper limit of the average thickness is preferably 1,000 nm, more preferably 500 nm, and still more preferably 300 nm.

### Method of Forming Pattern

The method of forming a pattern includes: a step of applying the composition (I) directly or indirectly on a substrate to form a resist underlayer film; a step of applying a composition for forming an organic resist film directly or indirectly on the resist underlayer film to form an organic resist film; a step of exposing the organic resist film to a radioactive ray; a step of developing the organic resist film exposed to form an organic resist pattern; a step of bringing the resist underlayer film into contact with a chlorine gas using the organic resist pattern as a mask; and a step of removing, with a removing liquid containing water or an organic solvent, the resist underlayer film brought into contact with chlorine gas.

Specifically, the method of forming a pattern includes: a step of applying the composition (I) on a substrate to form a resist underlayer film (hereinafter, may be also referred to as “applying step (I-1)”); a step of applying a composition for forming an organic resist film on the resist underlayer film to form an organic resist film (hereinafter, may be also referred to as “applying step (I-2)”); a step of exposing the organic resist film to a radioactive ray (hereinafter, may be also referred to as “exposing step”); a step of developing the organic resist film exposed to form an organic resist pattern (hereinafter, may be also referred to as “developing step”); a step of bringing the resist underlayer film into contact with a chlorine gas using the organic resist pattern as a mask (hereinafter, may be also referred to as “chlorine gas-contacting step”); and a step of removing, with a removing liquid containing water or an organic solvent, the resist underlayer film brought into contact with chlorine gas (hereinafter, may be also referred to as “removing step”).

The method of forming a pattern may further include as needed, before the applying step (I-1), a step of forming an organic underlayer film directly or indirectly on the substrate (hereinafter, may be also referred to as “organic underlayer film-forming step (I)”). As necessary, the method of forming a pattern may also include, before the applying step (I-2), a step of forming a silicon-containing film on the resist underlayer film formed in step (I-1).

Since the composition (I) is used, the method of forming a pattern enables forming a favorable pattern.

Hereinafter, each step included in the method of forming a pattern will be described.

Organic Underlayer Film-Forming Step (I)

In this step, the organic underlayer film is formed on the substrate. Examples of the organic underlayer film include organic underlayer films similar to those to be formed in the method of forming a reverse pattern, described later.

Applying Step (I-1)

In this step, the composition (I) is applied directly or indirectly on the substrate. In this step, the resist underlayer film is formed. The case of applying the composition (I) indirectly on the substrate may be exemplified by the case of applying the composition (I) on the organic underlayer film formed by the organic underlayer film-forming step (I). In this case, the resist underlayer film is formed on the organic underlayer film. This step is similar to the applying step in the method of producing a substrate, described above.

Silicon-Containing Film-Forming Step

In this step, the silicon-containing film is formed on the resist underlayer filmed formed by the applying step (I-1).

The silicon-containing film is typically formed by: hardening, by exposing and/or heating, the coating film formed by applying the composition for forming a silicon-containing film on the resist underlayer film. As a commercially available product of the composition for forming a silicon-containing film, for example, “NFC SOG01,” “NFC SOG04,” and “NFC SOG08,” each available from JSR Corporation, and the like may be used.

Examples of the radioactive ray to be used in the exposing include: electromagnetic waves such as a visible light ray, an ultraviolet ray, a far ultraviolet ray, an X-ray, and a γ-ray; particle rays such as an electron beam, a molecular beam, and an ion beam; and the like.

The lower limit of a temperature in heating the coating film is preferably 90° C., more preferably 150° C., and still more preferably 180° C. The upper limit of the temperature is preferably 550° C., more preferably 450° C., and still more preferably 300° C.

Applying Step (I-2)

In this step, the composition for forming an organic resist film is applied on the resist underlayer film formed by the applying step (I-1). In the case in which the silicon-containing film-forming step has been conducted, the composition for forming an organic resist film is applied on the silicon-containing film. In this step, the organic resist film is formed.

In this step, specifically, the organic resist film is formed by: applying the composition for forming an organic resist film such that a resultant organic resist film has a predetermined thickness, followed by heating the organic resist film to evaporate away the solvent contained in the coating film.

Examples of the composition for forming an organic resist film include: a chemically amplified positive or negative resist composition that contains a radiation-sensitive acid generating agent; a positive resist composition containing an alkali-soluble resin and a quinone diazide-based photosensitizing agent; a negative resist composition containing an alkali-soluble resin and a crosslinking agent; and the like.

The composition for forming an organic resist film is employed for forming the organic resist film, typically, after filtering through a filter having a pore size of no greater than 0.2 μm, for example. It is to be noted that in this step, a commercially available organic resist composition may be used directly.

A procedure for applying the composition for forming an organic resist film is not particularly limited, and is exemplified by a spin coating procedure and the like. Furthermore, a heating temperature may be appropriately adjusted in accordance with the type of the composition for forming an organic resist film used. The lower limit of the temperature of the heating is preferably 30° C., and more preferably 50° C. The upper limit of the temperature is preferably 200° C., and more preferably 150° C. The lower limit of a time period of the heating is preferably 10 sec, and more preferably 30 sec. The upper limit of the time period is preferably 600 sec, and more preferably 300 sec.

Exposing Step

In this step, the organic resist film formed by the applying step (I-2) is exposed to a radioactive ray.

The radioactive ray for use in the exposure may be appropriately selected from: electromagnetic waves such as a visible ray, an ultraviolet ray, a far ultraviolet ray, an X-ray, and a γ-ray; and particle rays such as an electron beam, a molecular beam, and an ion beam, depending on the type of the radiation-sensitive acid generating agent, quinone diazide-based photosensitizing agent, and crosslinking agent to be used in the composition for forming an organic resist film. Among these, far ultraviolet rays are preferred; and a KrF excimer laser beam (wavelength: 248 nm), an ArF excimer laser beam (wavelength: 193 nm), an F₂ excimer laser beam (wavelength: 157 nm), a Kr₂ excimer laser beam (wavelength: 147 nm), an ArKr excimer laser beam (wavelength: 134 nm), or an extreme ultraviolet ray (EUV; wavelength: 13.5 nm, etc.) is more preferred; and a KrF excimer laser beam, an ArF excimer laser beam, or an EUV is still more preferred.

Following the exposing, heating may be conducted to improve the resolution, pattern profile, developability, and the like. A temperature of the heating may be appropriately adjusted in accordance with the type of the composition for forming an organic resist film used. The lower limit of the temperature of the heating is preferably 50° C., and more preferably 70° C. The upper limit of the temperature is preferably 200° C., and more preferably 150° C. The lower limit of a time period of the heating is preferably 10 sec, and more preferably 30 sec. The upper limit of the time period is preferably 600 sec, and more preferably 300 sec.

Developing Step

In this step, the organic resist film exposed is developed. The development may be either a development with an alkali or a development with an organic solvent. In the case of the development with an alkali, examples of the developer solution include basic aqueous solutions of sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethyl ammonium hydroxide, pyrrole, piperidine, choline, 1,8-diazabicyclo[5.4.0]-7-undecene, 1,5-diazabicyclo[4.3.0]-5-nonene, or the like. To the basic aqueous solution, a water-soluble organic solvent, e.g., alcohols such as methanol and ethanol, a surfactant, etc., may be added each in an appropriate amount. Alternatively, in the case of the development with an organic solvent, examples of the developer solution include various organic solvents exemplified as the solvent (B) of the composition (I) described above, and the like.

A predetermined resist pattern is formed by the development with the developer solution, followed by washing and drying.

Chlorine Gas-Contacting Step

In this step, the resist underlayer film is brought into contact with a chlorine gas using the resist pattern formed in the developing step (I) as a mask. In this step, the resist underlayer film brought into contact with the chlorine gas becomes a film containing cobalt (II) chloride as a principal component, and is soluble in the removing liquid containing water or an organic solvent.

Removing Step

In this step, the resist underlayer film brought into contact with chlorine gas is removed with a removing liquid containing water or an organic solvent (hereinafter, may be also referred to as “removing liquid (I)”). In this step, a pattern of the resist underlayer film is formed.

Examples of the organic solvent include organic solvents exemplified as the organic solvent (b).

In the case in which the removing liquid (I) contains an acid, the removing liquid (I) may be exemplified by: a liquid containing an acid and water; a liquid obtained by mixing an acid, hydrogen peroxide, and water; and the like. Examples of the acid include sulfuric acid, hydrofluoric acid, hydrochloric acid, phosphoric acid, and the like. More specific examples of the removing liquid (I) containing the acid include: a liquid obtained by mixing hydrofluoric acid and water; a liquid obtained by mixing sulfuric acid, hydrogen peroxide, and water; a liquid obtained by mixing hydrochloric acid, hydrogen peroxide, and water; and the like.

In a case in which the removing liquid (I) contains a base, the removing liquid (I) may be exemplified by: a liquid containing a base and water; a liquid obtained by mixing a base, hydrogen peroxide, and water; and the like, and the liquid obtained by mixing a base, hydrogen peroxide, and water is preferred.

Examples of the base include sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethylammonium hydroxide, pyrrole, piperidine, choline, 1,8-diazabicyclo[5.4.0]-7-undecene, and 1,5-diazabicyclo[4.3.0]-5-nonene, and the like. Of these, ammonia is preferred.

The lower limit of a temperature in the removing step is preferably 20° C., more preferably 40° C., and still more preferably 50° C. The upper limit of the temperature is preferably 300° C., and more preferably 100° C.

The lower limit of a time period of the removing step is preferably 5 sec, and more preferably 30 sec. The upper limit of the time period is preferably 10 min, and more preferably 180 sec.

### Method of Forming Reverse Pattern

The method of forming a reverse pattern includes: a step of forming an organic underlayer film directly or indirectly on a substrate (hereinafter, may be also referred to as “organic underlayer film-forming step (II)”); a step of forming a resist pattern directly or indirectly on the organic underlayer film (hereinafter, may be also referred to as “resist pattern-forming step (II)”); a step of forming a film for forming a reverse pattern on the resist pattern (hereinafter, may be also referred to as “reverse pattern-forming film-forming step”); and a step of forming a reverse pattern by removing the resist pattern (hereinafter, may be also referred to as “reverse pattern-forming step”). In the method of forming a reverse pattern, the composition described above as the composition for forming a coating film (hereinafter, may be also referred to as “composition (II)”) is used in the reverse pattern-forming film-forming step.

The method of forming a reverse pattern enables forming a favorable reverse pattern due to using the composition (II).

The method of forming a reverse pattern may further include as needed, before the resister pattern-forming step, a step of forming a resist intermediate film (hereinafter, may be also referred to as “resist intermediate film-forming step”) on the organic underlayer film formed by the organic underlayer film-forming step (II).

Hereinafter, each step included in the method of forming a reverse pattern will be described.

Organic Underlayer Film-Forming Step (II)

In this step, the organic underlayer film is formed on the substrate. Examples of the substrate include substrates similar to the substrates which may be used in the applying step in the method of producing a substrate, described above.

The organic underlayer film can be formed from an organic compound. Examples of the organic compound include commercially available products such as “NFC HM8006,” available from JSR Corporation, and the like. The organic underlayer film can be formed by applying a composition for forming an organic underlayer film by spin coating or the like to form a coating film, and then heating the coating film.

The lower limit of an average thickness of the organic underlayer film to be formed is preferably 10 nm, more preferably 50 nm, and still more preferably 100 nm. The upper limit of the average thickness is preferably 1,000 nm, and more preferably 500 nm.

Resist Intermediate Film-Forming Step

In this step, the intermediate resist film is formed on the organic underlayer film formed by the organic underlayer film-forming step (II). Examples of the resist intermediate film include commercially available products such as: “NFC SOG01,” “NFC SOG04,” and “NFC SOG080,” each available from JSR Corporation, and the like. Alternatively, a polysiloxane, titanium oxide, aluminum oxide, tungsten oxide, or the like that is formed by a CVD process may be used. A procedure of forming the resist intermediate layer is not particularly limited, and for example, a coating procedure, a CVD process, or the like may be employed. Of these, the coating procedure is preferred. When the coating procedure is employed, the resist intermediate film may be consecutively formed after forming the organic underlayer film.

Resist Pattern-Forming Step (II)

In this step, the resist pattern is formed directly or indirectly on the organic underlayer film. The case of forming the resist pattern indirectly on the organic underlayer film may be exemplified by, for example, a case of forming the resist pattern on the resist intermediate film formed by the resist intermediate film-forming step. A procedure of forming the resist pattern may be exemplified by a well-known procedure such as a procedure of using a resist composition, a procedure in which a nanoimprint lithography technique is employed, and the like.

Reverse Pattern-Forming Film-Forming Step

In this step, the film for forming a reverse pattern is formed on the resist pattern. Specifically, in this step, the film for forming a reverse pattern is formed by applying the composition (II) on the substrate having the resist pattern formed thereon. In this case, the composition (II) is embedded into spaces of the resist pattern. Specifically, a procedure of applying the composition (II) on the substrate having the resist pattern formed thereon may be exemplified by a well-known procedure such as spin coating, cast coating, or roll coating. Furthermore, this step preferably includes a drying step, after the composition (II) is embedded into the spaces of the resist pattern. A drying procedure is not particularly limited, and the organic solvent (b) in the composition (II) can be evaporated away by baking, for example. Conditions of the baking may be appropriately adjusted depending on the blend composition of the composition (II), and a temperature of the baking is typically 80 to 250° C., and preferably 80 to 200° C. In a case in which the temperature of the baking is 80 to 180° C., a flattening step described later, particularly a flattening processing by a wet etching back procedure, can be smoothly carried out. It is to be noted that the heating time period is typically 10 to 300 sec, and preferably 30 to 180 sec. Furthermore, a thickness of the film for forming a reverse pattern to be obtained after the drying is not particularly limited, and is typically 10 to 1,000 nm, and preferably 20 to 500 nm.

Reverse Pattern-Forming Step

In this step, the resist pattern is removed to form the reverse pattern.

Specifically, first, the flattening processing is preferably carried out in order to expose an upper surface of the resist pattern. Next, the resist pattern is removed by dry etching or dissolving and removing, whereby a predetermined reverse pattern is obtained.

This reverse pattern-forming step enables forming on the substrate, a fine pattern having a high aspect ratio, which is difficult to achieve by a conventional lithography process. Accordingly, the fine pattern can be transferred to the substrate.

As a flattening procedure to be employed in the flattening processing, an etching procedure such as dry etching back or wet etching back, a CMP procedure, or the like may be employed. Of these, dry etching back in which a fluorine-based gas or the like is used, or wet etching back is preferred in light of the low cost. It is to be noted that processing conditions in the flattening processing are not particularly limited, and may be appropriately adjusted.

In addition, for removal of the resist pattern, dry etching is preferred, and specifically, oxygen-based gas etching, ozone etching, or the like is preferably employed. For the dry etching, a well-known apparatus such as an oxygen plasma ashing apparatus or an ozone ashing apparatus may be used. It is to be noted that the etching processing conditions are not particularly limited, and may be appropriately adjusted.

### Method of Forming Organic Underlayer Film Pattern

The reverse pattern formed by the method of forming a reverse pattern may be used, for example, as a mask at a time of patterning an organic underlayer film, or the like. In other words, the method of forming a reverse pattern may be suitably employed as a preceding step for the method of forming an organic underlayer film pattern, described below.

The method of forming an organic underlayer film pattern includes: a step of etching the organic underlayer film using as a mask, the reverse pattern formed by the method of forming a reverse pattern (hereinafter, may be also referred to as “organic underlayer film pattern-forming step”); and a step of bringing the reverse pattern into contact with a chlorine gas, followed by removing the reverse pattern with a removing liquid containing water or an organic solvent (hereinafter, may be also referred to as “reverse pattern-removing step”).

Organic Underlayer Film Pattern-Forming Step

In this step, the organic underlayer film is etched using as a mask, the reverse pattern formed by the method of forming a reverse pattern. The etching procedure may be exemplified by dry etching, wet etching, and the like. The dry etching may be carried out using a well-known dry etching apparatus. Furthermore, as the source gas used for dry etching: a fluorine-based gas such as CHF₃, CF₄, C₂F₆, C₃F₈, or SF₆; a chlorine-based gas such as Cl₂ or BCl₃; an oxygen-based gas such as O₂ or O₃; a reducing gas such as H₂, NH₃, CO, CO₂, CH₄, C₂H₂, C₂H₄, C₂H₆, C₃H₄, C₃H₆, C₃H₈, HF, HI, HBr, HCl, NO, NH₃, or NCl₃; an inert gas such as He, N₂, or Ar; or the like may be used, although the selection may depend on the elemental composition of the film to be etched, or a mixture of these gases may also be used. In dry etching the resist intermediate film in the case of forming the resist intermediate film, typically, a fluorine-based gas is used, and in dry etching the organic underlayer film, an oxygen-based gas may be suitably used.

Reverse Pattern-Forming Film-Removing Step

In this step, the reverse pattern is brought into contact with a chlorine gas, followed by removing with a removing liquid containing water or an organic solvent. In this step, the reverse pattern, having been brought into contact with the chlorine gas, becomes a film containing cobalt (II) chloride as a principal component, and is removed due to being soluble in the removing liquid, which contains water or the organic solvent.

The removing liquid used in this step is similar to the removing liquid (I) in the removing step of the method of forming a pattern, described above.

### Formation of Damascene Structure

A cobalt metal layer (wiring layer) may be formed by: applying the composition for forming a coating film on a low dielectric insulating film having a pattern formed thereon to permit embedding into the pattern (wiring grooves); and heating the coating film. Before applying the composition for forming a coating film, a barrier metal film may be formed. Following forming the cobalt metal layer, a part of the cobalt metal layer is removed by chemical mechanical polishing (CMP), thereby exposing a surface of the low dielectric insulating film and enabling flattening. Applying conditions and heating conditions may be similar to those of the applying step and the heating step in the method of producing a substrate of the another embodiment of the present invention.

### EXAMPLES

Hereinafter, Examples are described. It is to be noted that the following Examples merely illustrate typical Examples of the embodiments of the present invention, and the Examples should not be construed to narrow the scope of the present invention.

Average Thickness of Film

An average thickness of the film was measured by using an X-ray diffraction apparatus (“SmartLab,” available from Rigaku Corporation).

### Preparation of Composition for Forming Coating Film

The compound (A), the solvent (B), and the other organic compound (C) used in preparing the composition for forming a coating film are shown below.

(A) Compound

Compounds (A-1) to (A-6) and (a-1) to (a-2): the structure of each compound is shown by the following formulae (A-1) to (A-6) and (a-1) to (a-2).

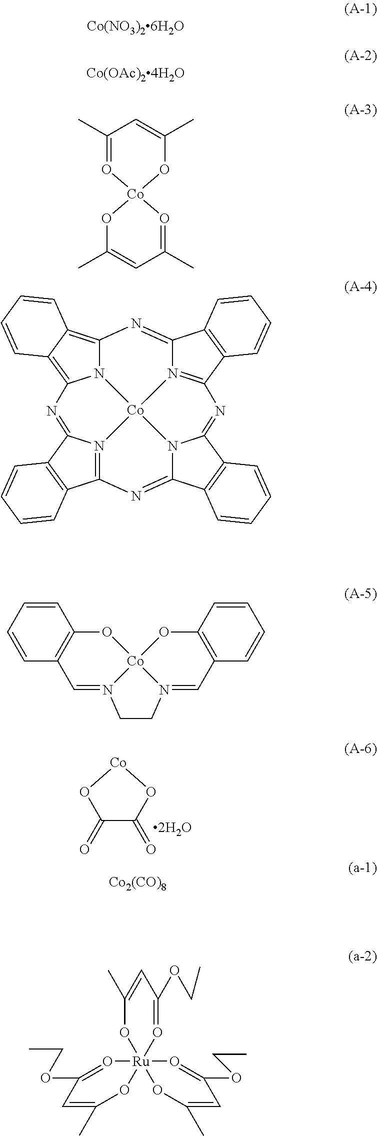

(B) Solvent

B-1: propylene glycol monoethyl ether

B-2: ethyl lactate

B-3: n-butyl alcohol

B-4: propylene glycol monomethyl ether acetate

B-5: ethylene glycol

B-6: 1,2-butanediol

B-7: diethylene glycol

B-8: triethanolamine

B-9: water

B-10: 2-hydrazinoethanol (a compound represented by the following formula (B-10))

B-11: 1-hydroxy-2-propanone hydrazone (a compound represented by the following formula (B-11))

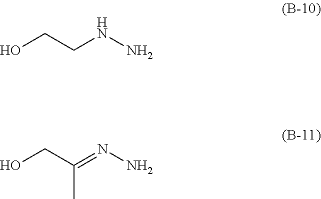

(C) Other Organic Compound

C-1: citric acid (a compound represented by the following formula (C-1))

C-2: ascorbic acid (a compound represented by the following formula (C-2))

C-3: gallic acid (a compound represented by the following formula (C-3))

C-4: acetic acid hydrazide (a compound represented by the following formula (C-4))

C-5: methyl carbazate (a compound represented by the following formula (C-5))

C-6: cyanoacetic acid hydrazide (a compound represented by the following formula (C-6))

C-7: salicylic acid hydrazide (a compound represented by the following formula (C-7))

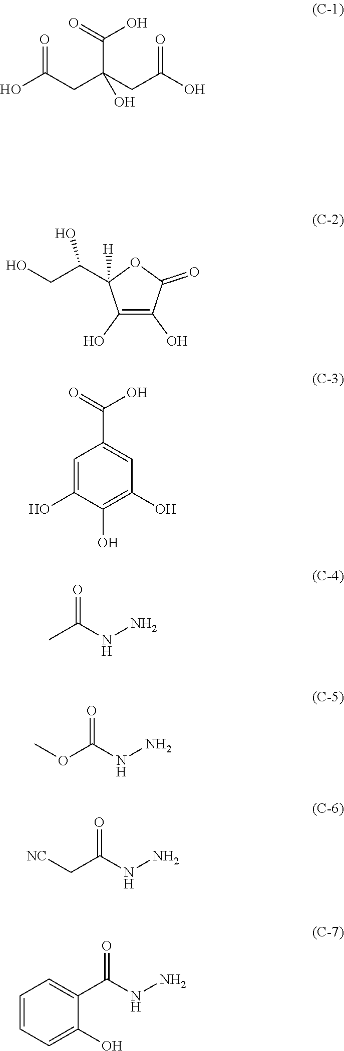

### Example 1

A composition for forming a coating film (J-1) was prepared by: mixing 18 parts by mass of (A-1) and 2 parts by mass of (A-2) as the compound (A), and 80 parts by mass of (B-1) as the solvent (B) together; and filtering a thus obtained solution through a nylon syringe filter having a pore size of 0.2 μm.

### Examples 2 to 24 and Comparative Examples 1 to 2

Compositions for forming coating films (J-2) to (J-24) and (j-1) to (j-2) were prepared in a similar manner to Example 1, except that for each component, the type and content shown were as shown in Table 1 below. In Table 1, “-” indicates that a corresponding component was not used.

TABLE 1

| | | | | (B) Solvent | | (C) Other organic | |
|---|---|---|---|---|---|---|---|
| | Composition | (A) Compound | | | content | compound | |
| | for forming | | content (parts | | (parts by | | content (parts |
| — | coating film | Type | by mass) | type | mass) | type | by mass) |
| Example 1 | J-1 | A-1/A-2 | 18/2 | B-1 | 80 | — | — |
| Example 2 | J-2 | A-1/A-3 | 18/2 | B-1 | 80 | — | — |
| Example 3 | J-3 | A-1/A-4 | 18/2 | B-1 | 80 | — | — |
| Example 4 | J-4 | A-1/A-5 | 18/2 | B-1 | 80 | — | — |
| Example 5 | J-5 | A-1/A-6 | 18/2 | B-1 | 80 | — | — |
| Example 6 | J-6 | A-1/A-2 | 18/2 | B-2 | 80 | — | — |
| Example 7 | J-7 | A-1/A-2 | 18/2 | B-3 | 80 | — | — |
| Example 8 | J-8 | A-1/A-2 | 18/2 | B-1/B-9 | 60/20 | — | — |
| Example 9 | J-9 | A-1/A-2 | 18/2 | B-1/B-5 | 70/10 | — | — |
| Example 10 | J-10 | A-1/A-2 | 18/2 | B-1/B-6 | 70/10 | — | — |
| Example 11 | J-11 | A-1/A-2 | 18/2 | B-1/B-7 | 70/10 | — | — |
| Example 12 | J-12 | A-1/A-2 | 18/2 | B-1/B-8 | 70/10 | — | — |
| Example 13 | J-13 | A-1/A-2 | 18/2 | B-1 | 70 | C-1 | 10 |
| Example 14 | J-14 | A-1/A-2 | 18/2 | B-1 | 70 | C-2 | 10 |
| Example 15 | J-15 | A-1/A-2 | 18/2 | B-1 | 70 | C-3 | 10 |
| Example 16 | J-16 | A-1/A-2 | 18/2 | B-1/B-10 | 65/15 | — | — |
| Example 17 | J-17 | A-1 | 20 | B-1/B-10 | 65/15 | — | — |
| Example 18 | J-18 | A-2 | 20 | B-1/B-10 | 65/15 | — | — |
| Example 19 | J-19 | A-2 | 20 | B-10 | 80 | — | — |
| Example 20 | J-20 | A-2 | 20 | B-1/B-11 | 65/15 | — | — |
| Example 21 | J-21 | A-2 | 20 | B-1 | 65 | C-4 | 15 |
| Example 22 | J-22 | A-2 | 20 | B-1 | 65 | C-5 | 15 |
| Example 23 | J-23 | A-2 | 20 | B-1 | 65 | C-6 | 15 |
| Example 24 | J-24 | A-2 | 20 | B-1 | 65 | C-7 | 15 |
| Comparative | j-1 | a-1 | 20 | B-4 | 80 | — | — |
| Example 1 | | | | | | | |
| Comparative | j-2 | a-2 | 20 | B-1 | 80 | — | — |
| Example 2 | | | | | | | |

### Evaluations

Each of the compositions for forming coating films (J-1) to (J-24) and (j-1) to (j-2) prepared as described above was evaluated by the following methods on storage stability, and on conductivity and an embedding property of a cobalt-containing film formed. The results of the evaluations are shown in Table 2 below.

Storage Stability

The storage stability of each composition for forming a coating film was evaluated by a difference in coating characteristics in accordance with passage of time. Each composition for forming a coating film immediately after preparation as described above (T=0) was applied on a cobalt substrate by a spin coating procedure using a spin coater (“MS-B200,” available from MIKASA Co., Ltd.) under a condition involving 1,500 rpm and 30 sec, followed by heating a thus obtained coating film in a nitrogen atmosphere at 500° C. for 300 sec using an RTA furnace (“QHC-P610CP,” available from ULVAC, Inc.), whereby a cobalt-containing film was formed. With regard to the coating characteristics, each cobalt-containing film thus formed was observed with an optical microscope, and evaluated to be: “A” (favorable) in a case of finding no coating unevenness; and “B” (unfavorable)” in a case of finding coating unevenness. Furthermore, each composition for forming a coating film, having been evaluated on the coating characteristics, was stored at 25° C. for seven days (T=7) and then similarly subjected to a coating characteristics evaluation, and evaluated similarly. The storage stability can be evaluated to be: favorable in a case in which both the coating characteristics at T=0 and the coating characteristics at T=7 are “A” (favorable); and unfavorable in a case in which at least one of the coating characteristics is not “A.”.

Conductivity

Each composition for forming a coating film immediately after preparation as described above was applied on a silicon substrate by a spin coating procedure using the spin coater (“MS-B200,” available from MIKASA Co., Ltd.). Next, a thus obtained coating film was heated in a nitrogen atmosphere at 500° C. for 300 sec using the RTA furnace (“QHC-P610CP,” available from ULVAC, Inc.), and subsequently cooled at 23° C. for 60 sec to form a cobalt-containing film having an average thickness of 200 nm, thereby giving a cobalt-containing film-attached silicon substrate. A specific resistivity of the cobalt-containing film in the cobalt-containing film-attached silicon substrate was measured by a direct current 4-probe method using a resistivity-measuring instrument (“Σ-5,” available from NPS Corporation). The conductivity was evaluated to be: “S” (extremely favorable) in a case in which the specific resistivity was no greater than 25.0 μΩ/cm; “A” (favorable) in a case in which the specific resistivity was greater than 25.0 μΩ/cm and no greater than 50.0 μΩ/cm; and “B” (unfavorable) in a case in which the specific resistivity was greater than 50.0 μΩ/cm.

Embedding Property

Each composition for forming a coating film prepared as described above was applied on a silicon substrate, the substrate having a line-and-space pattern with a depth of 400 nm and a width of 45 nm formed thereon, by a spin coating procedure using the spin coater (“MS-B200,” available from MIKASA Co., Ltd.). Next, a thus obtained coating film was heated in a nitrogen atmosphere at 500° C. for 300 sec using the RTA furnace (“QHC-P610CP,” available from ULVAC, Inc.), and subsequently cooled at 23° C. for 60 sec to form a cobalt-containing film having an average thickness of 50 nm at line pattern parts, thereby giving a cobalt-containing film-attached silicon substrate. A cross-sectional shape of the cobalt-containing film-attached silicon substrate was observed with a scanning electron microscope (“SU8220,” available from Hitachi High-Technologies Corporation) to evaluate the embedding property. The embedding property was evaluated to be: “A” (favorable) in a case in which the cobalt-containing film was embedded to a bottom part of the space pattern; and “B” (unfavorable) in a case in which the cobalt-containing film was not embedded to a bottom part of the pattern.

TABLE 2

| | Composition | | | | |
|---|---|---|---|---|---|
| | for forming | Storage stability | | | Embedding |
| — | coating film | T = 0 | T = 7 | Conductivity | property |
| Example 1 | J-1 | A | A | A | A |
| Example 2 | J-2 | A | A | A | A |
| Example 3 | J-3 | A | A | B | A |
| Example 4 | J-4 | A | A | B | A |
| Example 5 | J-5 | A | A | A | A |
| Example 6 | J-6 | A | A | A | A |
| Example 7 | J-7 | A | A | A | A |
| Example 8 | J-8 | A | A | A | A |
| Example 9 | J-9 | A | A | A | A |
| Example 10 | J-10 | A | A | A | A |
| Example 11 | J-11 | A | A | A | A |
| Example 12 | J-12 | A | A | A | A |
| Example 13 | J-13 | A | A | A | A |
| Example 14 | J-14 | A | A | A | A |
| Example 15 | J-15 | A | A | A | A |
| Example 16 | J-16 | A | A | S | A |
| Example 17 | J-17 | A | A | S | A |
| Example 18 | J-18 | A | A | S | A |
| Example 19 | J-19 | A | A | S | A |
| Example 20 | J-20 | A | A | S | A |
| Example 21 | J-21 | A | A | S | A |
| Example 22 | J-22 | A | A | S | A |
| Example 23 | J-23 | A | A | S | A |
| Example 24 | J-24 | A | A | S | A |
| Comparative | j-1 | A | B | B | B |
| Example 1 | | | | | |
| Comparative | j-2 | A | A | B | B |
| Example 2 | | | | | |

As is seen from the results shown in Table 2, the compositions for forming coating films of the Examples are superior in storage stability, and cobalt-containing films formed therewith are superior in conductivity and the embedding property.

The composition for forming a coating film of the one embodiment of the present invention is superior in storage stability. Due to using the composition for forming a coating film of the one embodiment of the present invention, the method of producing a substrate of the another embodiment of the present invention enables forming a cobalt-containing film which is superior in conductivity and an embedding property. Therefore, these can be suitably used in formation of a cobalt-containing film in a semiconductor field, a battery material field, and the like.

Obviously, numerous modifications and variations of the present invention are possible in light of the above teachings. It is therefore to be understood that within the scope of the appended claims, the invention may be practiced otherwise than as specifically described herein.

What is claimed is:

1. A composition comprising:
a cobalt-containing compound not comprising a cobalt-carbon bond; and
a solvent,
wherein the composition is capable of forming a coating film.

2. The composition according to claim 1, wherein the solvent comprises an organic solvent, and
the organic solvent comprises an alcohol solvent.

3. The composition according to claim 2, wherein the alcohol solvent is a monohydric alcohol, a polyhydric alcohol partial ether, a lactic acid ester, a hydrazino alcohol, a hydroxy ketone hydrazone, or a combination thereof.

4. The composition according to claim 2, wherein a proportion of the alcohol solvent in the organic solvent is no less than 50% by mass.

5. The composition according to claim 1, wherein the cobalt-containing compound is: a cobalt salt of nitric acid, sulfuric acid, or carboxylic acid; a complex comprising cobalt and a ligand; or a combination thereof.

6. The composition according to claim 1, wherein a proportion of the cobalt-containing compound with respect to total components other than the solvent is no less than 50% by mass.

7. A method of producing a substrate, the method comprising:
applying a composition directly or indirectly on a substrate to form a coating film, wherein
the composition comprises:
a cobalt-containing compound not comprising a cobalt-carbon bond; and
a solvent.

8. The method according to claim 9, further comprising heating the coating film.

9. A method of forming a pattern, the method comprising:
applying the composition according to claim 1 directly or indirectly on a substrate to form a resist underlayer film;
applying a composition for forming an organic resist film directly or indirectly on the resist underlayer film to form an organic resist film;
exposing the organic resist film to a radioactive ray;
developing the organic resist film exposed to form an organic resist pattern;
bringing the resist underlayer film into contact with a chlorine gas using the organic resist pattern as a mask; and
removing the resist underlayer film, with a removing liquid comprising water or an organic solvent.

10. The method according to claim 9, wherein the solvent comprises an organic solvent, and
the organic solvent comprises an alcohol solvent.

11. The method according to claim 10, wherein the alcohol solvent is a monohydric alcohol, a polyhydric alcohol partial ether, a lactic acid ester, a hydrazino alcohol, a hydroxy ketone hydrazone, or a combination thereof.

12. The method according to claim 10, wherein a proportion of the alcohol solvent in the organic solvent is no less than 50% by mass.

13. The method according to claim 9, wherein the cobalt-containing compound is: a cobalt salt of nitric acid, sulfuric acid, or carboxylic acid; a complex comprising cobalt and a ligand; or a combination thereof.

14. The method according to claim 9, wherein a proportion of the cobalt-containing compound with respect to total components other than the solvent is no less than 50% by mass.

15. A method of forming a reverse pattern, the method comprising:
forming an organic underlayer film directly or indirectly on a substrate;
forming a resist pattern directly or indirectly on the organic underlayer film;
forming a film for forming a reverse pattern on the resist pattern by applying the composition according to claim 1; and
forming a reverse pattern by removing the resist pattern.

16. The method according to claim 15, wherein the solvent comprises an organic solvent, and
the organic solvent comprises an alcohol solvent.

17. The method according to claim 16, wherein the alcohol solvent is a monohydric alcohol, a polyhydric alcohol partial ether, a lactic acid ester, a hydrazino alcohol, a hydroxy ketone hydrazone, or a combination thereof.

18. The method according to claim 16, wherein a proportion of the alcohol solvent in the organic solvent is no less than 50% by mass.

19. The method according to claim 15, wherein the cobalt-containing compound is: a cobalt salt of nitric acid, sulfuric acid, or carboxylic acid; a complex comprising cobalt and a ligand; or a combination thereof.

20. The method according to claim 15, wherein a proportion of the cobalt-containing compound with respect to total components other than the solvent is no less than 50% by mass.
